(19) United States
(12) Patent Application Publication
(10) Pub. No.: US 2009/0309588 A1
(43) Pub. Date: Dec. 17, 2009

(54) SYSTEM AND METHODS FOR ACTUATION ON MAGNETORESISTIVE SENSORS

(75) Inventors: Jeroen Hans Nieuwenhuis, Eindhoven (NL); Petrus Johannes Wilhelmus Van Lankvelt, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/299,783

(22) PCT Filed: May 9, 2007
(86) PCT No.: PCT/IB2007/051749

§ 371 Date: Mar. 4, 2009

(30) Foreign Application Priority Data
May 10, 2006 (EP) 06113766.7

(51) Int. Cl. G01N 27/72; G01R 33/09

(52) U.S. Cl. 324/232; 324/252

(57) ABSTRACT

The present invention relates to systems and methods for magnetic actuation of particles from and toward the surface of a sensor with a magneto-resistive element. The orientation of magnetic fields and arrangement of magnetic field generating means with respect to the sensor maintains or restores the sensitivity of the magneto-resistive element after actuation.

The invention relates to methods and systems for combining magnetic actuation in sensor systems having magnetoresistive sensor elements. The present invention is particularly relevant to biosensors and methods of operating the same.

Biosensor devices have been developed that measure the presence of certain analytes, based on capture and labeling the analytes with magnetic particles such as described in WO2005010542. These magnetic particles are brought into the proximity of a GMR-type magneto-resistive sensor. This sensor measures the magnetic stray-field of magnetic particles. From this signal, the concentration of the analyte is calculated. Such sensors are particularly suited for point-of-care applications where a low concentration of analyte is to be measured, often in small volumes of sample. GMR based biosensors are for example described in US20040120185.

Traditional washing steps based on the flow of liquid over the sensor surface can be replaced by magnetic washing steps, where the unbound or non-specifically or non-selectively bound particles can be pulled from the surface with a magnetic field.

Magnetic actuation can also be used to actively pull the magnetic particles towards the sensor surface, instead of relying on sedimentation and diffusion of the particles. Consequently, magnetic actuation can greatly speed-up measurements. In addition, a measurement can also be performed with the sensor having an arbitrary geometric orientation, since it no longer relies on gravity to get the particles on the sensor surface.

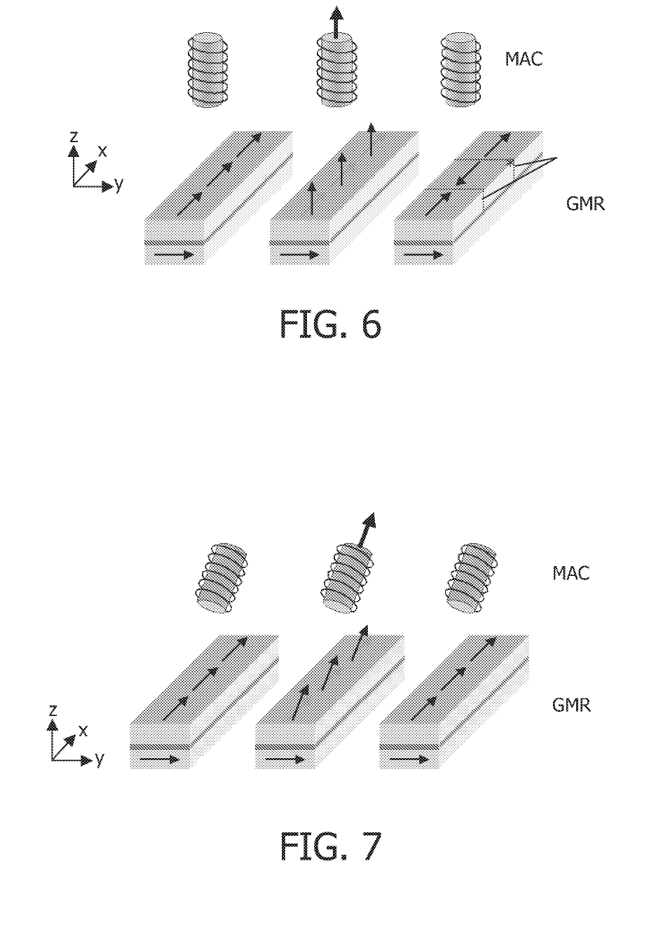

Magnetic actuation in the presence of a very sensitive magneto-resistive sensor such as a GMR sensor is however not trivial. Applied magnetic fields suitable to manipulate particle generally are so strong that they modify the magnetization of the free layer of a sensor of the GMR type (see FIG. 6). The same problem is illustrated in FIG. 6b. When a strong magnetic actuation field is applied perpendicular to the sensor surface (FIG. 6b), it can alter the magnetization of the free-layer of the GMR-sensor. With extreme high forces the magnetic field pulls the magnetic domains out of the sensor surface and when the field is switched off the magnetic domains can fall back in either direction along the long axis of the sensor strip (FIG. 6c). Lower forces also can alter magnetization of the free layer without pulling the magnetic domains out of the sensor surface. This can lead to the formation of new magnetic grain boundaries, resulting in a sensitivity that is modified in an uncontrolled way. A biosensor, wherein a spin-valve sensor is combined with magnetic actuation is described by Lagae et al. (2002) J. Appl. Phys. 91, 7445.

There is a need for more sensitive devices wherein strong magnetic actuation fields can be applied without adversely affecting the properties of a magnetoresistive sensor such as GMR-sensors.

It is an object of the present invention to provide improved methods and systems for combining magnetic actuation in sensor systems having magnetoresistive sensor elements.

In one aspect the present invention relates to a system for measuring the presence of at least one magnetic particle at the surface of a sensor comprising a sensor with a magnetoresistive element and comprising one or more magnetic field generators arranged around the sensor at a distance arranged to generate a magnetic field at the sensor, characterized in that one or more magnetic field generators generate a field with a component in the plane of the sensor.

Herein the field with a component in the plane of the sensor is strong enough to substantially magnetically saturate the one or more free magnetic layers of the sensor, without substantially affecting the other layers in the sensor.

According to one embodiment one or two magnetic field generators are positioned each to generate a magnetic field with a first angle (alpha) with a longitudinal axis of the sensor.

According to another embodiment said one or two magnetic field generators are placed to generate each a magnetic field with a second angle (beta) to the transverse axis of the sensor.

According to another embodiment one or two magnetic field generators are positioned to generate a magnetic field at an angle perpendicular to the surface of the sensor, and further comprise a magnetic field generator which is placed to generate a magnetic field with a third angle (gamma) and/or fourth angle (delta) with the surface of the sensor. In a specific embodiment the third and fourth angles (gamma and delta) are 0°.

According to another embodiment one magnetic field generator is positioned to generate a magnetic field perpendicular to the surface of the sensor, and further comprising a second magnetic field generator which is positioned to generate a magnetic field with a first angle (alpha) to a longitudinal axis of the sensor and/or a second angle (beta) to a transverse axis of the sensor.

In the system of the present invention the magnetoresistive sensor can be a GMR sensor.

In the system of the present invention one or more magnetic field generators can be electromagnets. In one embodiment a magnetic field generator is an on-chip current wire.

The system can further comprise magnetic particles and an analyte can be bound to these magnetic particles. When the analyte is a molecules such as DNA, RNA, a (poly)peptide, a carbohydrate a lipid, a pharmaceutical compound, a protein ligand or the like, the system of the present invention can be used as a biosensor.

In the present system it is also possible to have probes attached to the measurement surface which can interact or bind with the analytes on the magnetic particles.

Another aspect of the invention relates to the use of magnetic field generators arranged around a magnetoresistive element of a sensor to manipulate magnetic particles towards and from the surface of said sensor whereby the magnetization of the surface prior to the manipulation is maintained or restored compared to said magnetic field prior to said manipulation. Herein analyte is bound to said magnetic particles and/or a probe is attached to a measurement surface near the sensor surface. The arrangement of the magnetic field generators arranged around a magnetoresistive element of a sensor can be used in biosensors.

Another aspect of the invention relates to a method for manipulating magnetic particles towards and from the surface of a sensor with a magnetoresistive element comprising the steps of manipulating said particles one or more times to or from the sensor surface with a magnetic field with a direction other than perpendicular to the sensor surface or manipulating said particles one or more times to or from the sensor surface with a magnetic field with a direction perpendicular to the sensor surface followed by applying a magnetic field having a component along a longitudinal axis of the surface of the sensor.

The manipulation of the method can further comprise the step of measuring the presence of at least one magnetic particle accumulated at the surface of the sensor. In this method the sensor can be a GMR sensor. In this method, the magnetic fields can be generated by electromagnets or coils or wires.

The present invention discloses sensor systems and methods for actuating particles using magnetoresistive sensors such as a GMR based sensor. By applying a strong magnetic actuation field at an angle with a component along the longitudinal axis of the sensor (e.g. a “sensor surface”), such magnetic actuation field does not adversely affect the sensitivity of the sensor because with this configuration of the actuation field the free layer of a sensor is reset during actuation, resulting in a well-defined state before the start of a measurement. Alternatively a sensor, which has been distorted by a magnetic actuation is reset with a magnetic field that has a different orientation than the actuation field.

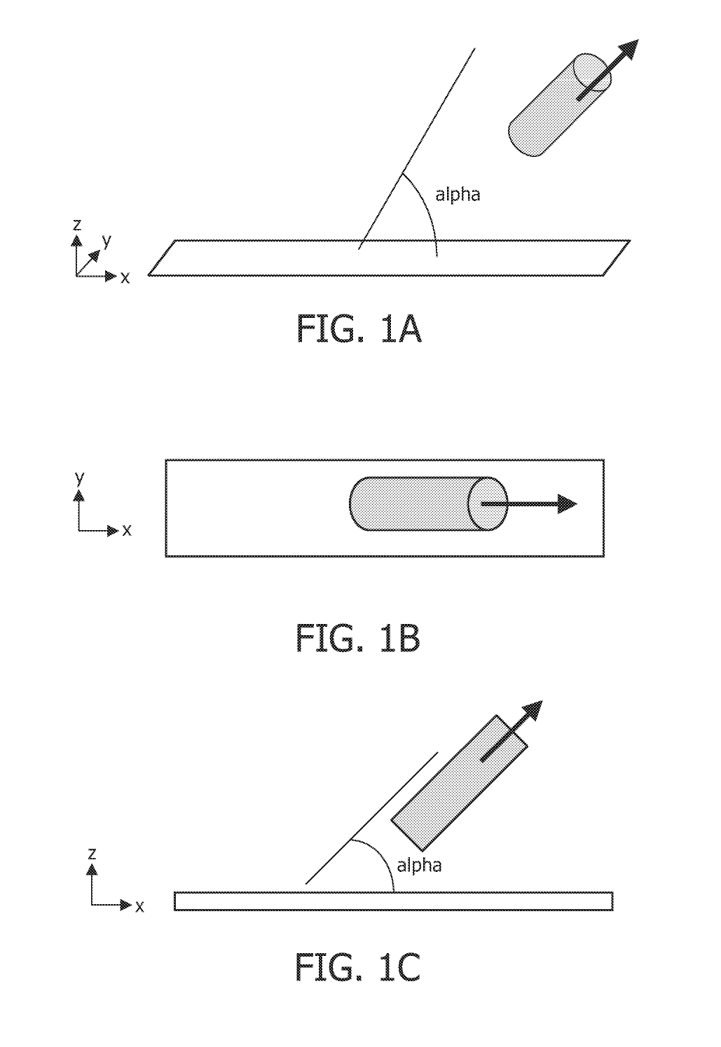

FIG. 1 illustrates a first (alpha) orientation of a magnetic actuation field according to an embodiment of the present invention. FIG. 1a shows a perspective view. FIG. 1b shows a top view on the surface of the sensor. FIG. 1c shows a side view along the longitudinal side of the sensor.

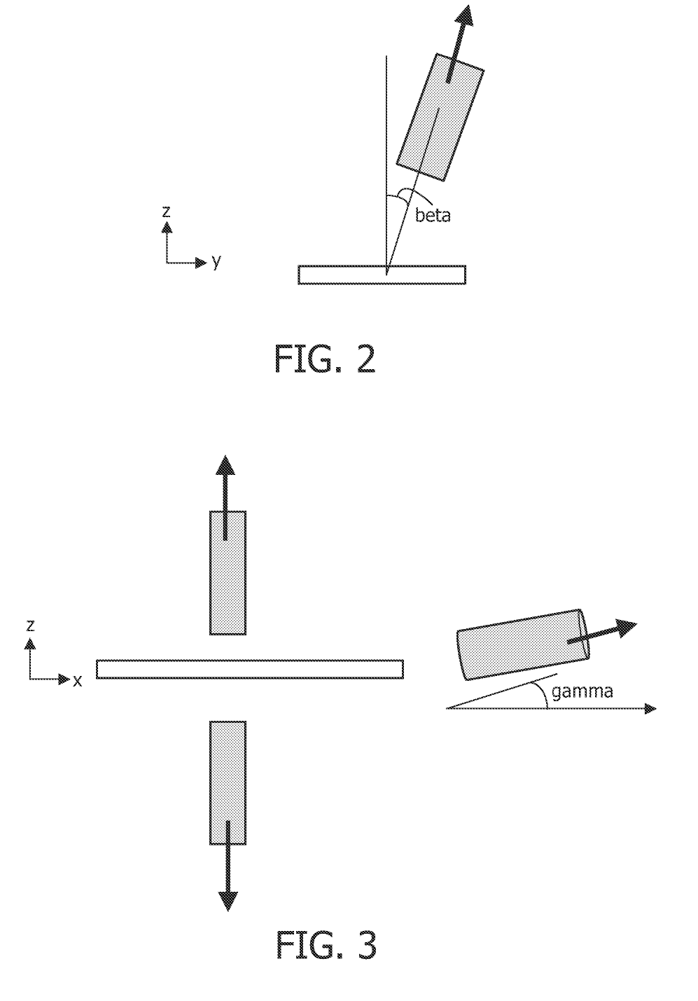

FIG. 2 illustrates a second (beta) orientation of a magnetic actuation field according to an embodiment of the present invention. The Figure shows a side view along the lateral of the sensor surface.

FIG. 3 illustrates a third (gamma) orientation of a magnetic reset field according to an embodiment of the present invention. The Figure is a side view along the longitudinal side of the sensor surface.

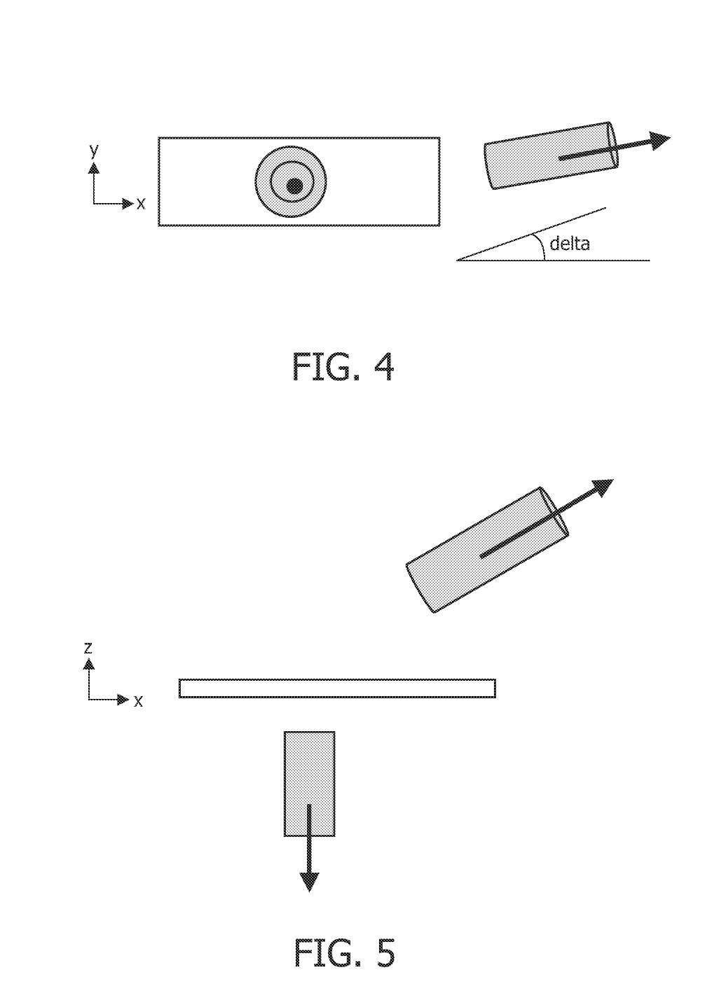

FIG. 4 illustrates a fourth (delta) orientation of a magnetic reset field according to an embodiment of the present invention. The Figure shows a top view on the sensor surface.

FIG. 5 illustrates a configuration of a sensor with one magnetic actuation field positioned perpendicular to the surface of the sensor and a magnetic actuation/reset field positioned at a first angle (alpha) and/or at a second angle (beta) with the sensor surface according to an embodiment of the present invention.

FIG. 6 shows an embodiment of a GMR sensor (GMR) configuration with magnetic actuation coils (MAC) generating a magnetic field perpendicular to the surface of a GMR sensor according to an embodiment of the present invention. Newly formed magnetic boundaries are indicated with an asterisk.

FIG. 7 shows an embodiment of a GMR sensor configuration with magnetic actuation coils generating a magnetic field at an angle other than perpendicular to the surface of the GMR sensor.

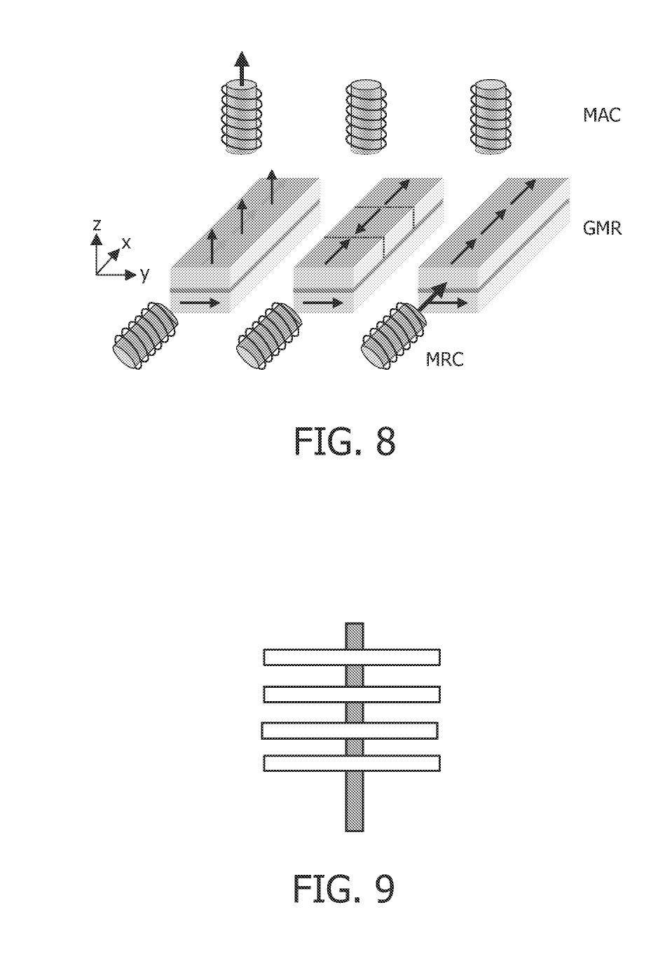

FIG. 8 shows an embodiment of a GMR sensor configuration with magnetic actuation coils generating a magnetic field perpendicular to the surface of the GMR sensor and a magnetic reset coil (MRC) generating a field along the length of the GMR sensor surface.

FIG. 9 shows a top view of a GMR sensor, above or below which current lines are present. The current lines can generate an in-plane field at the location of the GMR sensor.

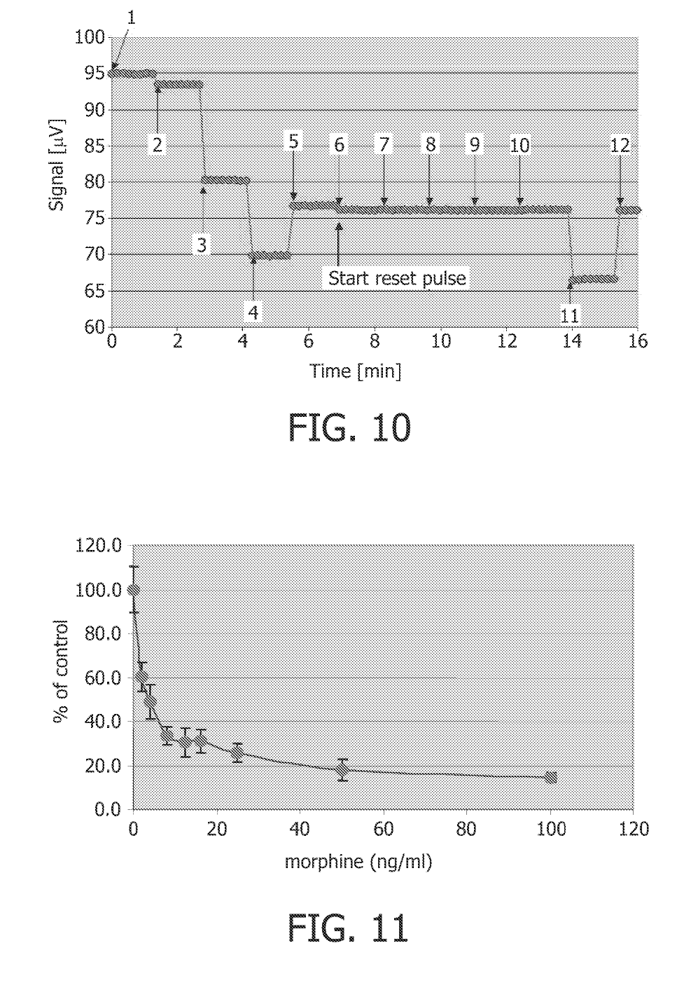

FIG. 10 shows the measured signal of a magneto-resistive sensor as a function of times using different actuation and reset conditions (see example 2).

FIG. 11 shows a competition assay with magnetic actuation and GMR detection of antibody coated magnetic particles (magnetic actuation during 1 minute).

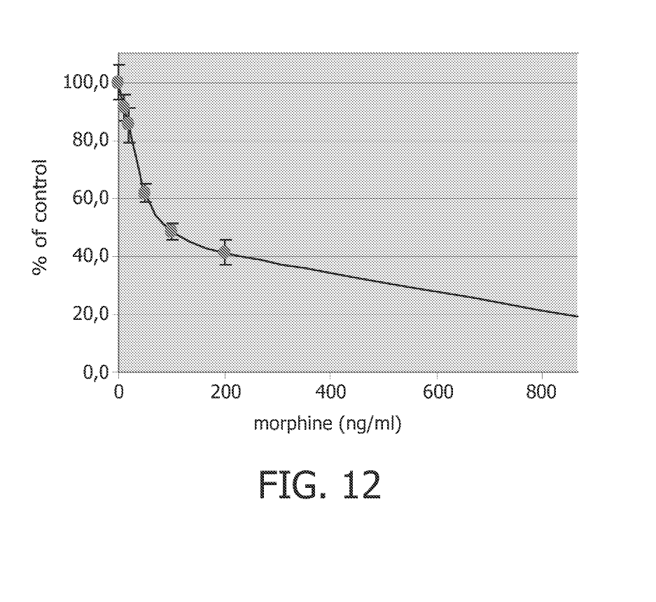

FIG. 12 shows a competition assay with magnetic actuation and GMR detection of antibody coated magnetic particles (magnetic actuation during 5 minutes).

In FIGS. 1-9, arrows show the magnetization on the sensor or show the magnetic field from the magnets.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

The present invention relates to a system for detecting magnetic particles on sensors with magnetoresistive elements after magnetic actuation, said system comprising a sensor such as a GMR sensor and one or more magnetic field generators, e.g. permanent magnets, electromagnets, coils or wires. To maintain or restore a well-defined sensitivity of a magneto-resistive sensor, the direction of magnet domains in the sensor material, applied magnetic fields and sensor are oriented in a defined configuration with respect to each other.

The invention relates to systems such as (bio)sensors which detect the presence and amounts of magnetic particles in a sample, such as a fluid, a liquid, a gas, a visco-elastic medium, a gel or a tissue sample. Typically, in such a system the sensor is below a measurement surface whereby the sensor surface is parallel with the measurement surface. The liquid, gas or other medium comprising magnetic particles which should come in contact with the measurement surface are positioned near the measurement surface. Generally, the sensor surface and measurement surface are in a horizontal configuration. However other configurations are equally possible.

The magnetic sensors used in a system of the present invention are magnetoresistive devices, such as AMR, GMR or TMR devices (reviewed in Coehoorn R., “Giant magnetoresistance and magnetic interactions in exchange-biased spin-valves”, Handbook of Magnetic Materials, vol. 15, ed. E. Buschow, Elsevier, 2003.

The invention is applicable to any sensor wherein a magnetic layer is used to measure the stray field of a particle in its neighborhood. In particular the present invention relates to sensors which rely on the magnetization of a free layer, i.e. a layer that can be affected by externally applied magnetic fields. According to one embodiment of the invention, the magnetic sensors are GMR sensors. GMR sensors consist of a stack of two magnetic layers, separated by a very thin non-magnetic layer. The impedance of the GMR-sensor depends on the direction of magnetization of the two magnetic layers. When the magnetization of these layers is opposite, the impedance reaches a maximum level. Parallel alignment of the magnetization results in minimum impedance. For a (bio)sensor, GMR-elements are fabricated in such a way that the magnetization of the two layers is orthogonal (see FIG. 6a). In FIG. 6a the magnetic domains of the sensor are lifted out of the plane of the sensor. Such configuration is shown for the purpose of illustration and only occurs when very strong fields are applied perpendicular to the sensor surface. However, a distortion of the magnetic field in the free layer of the sensor, without magnetic domains being lifted out of the plane of the sensor, can also be obtained when smaller magnetic fields are applied.

The magnetization of the bottom layer of the sensor is fixed and the magnetization of the top layer can rotate under the influence of the stray field of magnetic particles. Generally GMR sensors have an elongated, e.g. a long and narrow stripe, geometry but the invention is not limited to this geometry. (Bio)sensor systems which are based on GMR detection are explained in detail in WO 2005/010542.

(Bio)sensing systems of the present invention generally have a sensor which is positioned under a measurement surface that is modified with probes (e.g. oligonucleotides, peptides, antibodies or antigens or small molecules such as library compounds). Different probes can be arrayed by attaching them at different parts of the measurement surface or on different and separate measurement surfaces. Such an array can be combined with different magnetic sensor elements to measure the presence and concentration of different analytes in one assay. According to this embodiment, a sample with an analyte that can specifically bind to probes on the measurement surface is introduced into the system. The analyte itself can be labeled with a magnetic particle, or a further molecule with a magnetic particle can bind to the bound analyte-probe complex. In the present invention actuation is used to enhance the transport of magnetic particles to the measurement surface and/or to remove unbound and a specifically bound magnetic particles from the measurement surface.

In another embodiment the measurement surface is not modified with probes. In such assay magnetic particles with a compound of interest attached thereto have been assembled and/or isolated previously and are brought to the measurement surface for qualitative and quantitative measurement.

Magnetic particles used in a bio(sensor) are generally very small, in the order of a few hundred nanometer in diameter. Particles have at least one dimension ranging between 1 nm and 6000 nm, preferably between 30 nm and 3000 nm, more preferred between 100 nm and 1000 nm. They are normally round, but can also be rod-like, oval or have other shapes. The particles typically consist of a polymer matrix in which small grains of magnetic material have been integrated or are present as a coating on a polymer particle, so the particles only partially consist of magnetic material.

As long as the particles generate a non-zero response to application of a magnetic field, i.e. when they generate a magnetic susceptibility or permeability, they can be used. These magnetic particles create very small magnetic stray fields. The stray fields depend strongly on the particle size and particle type In order to detect small numbers of magnetic particles the sensor is preferably designed with a very high sensitivity, capable of detecting for example thousands of particles, or even single particles at a concentration of 1 particle per 1000 μm².

The analytes used in the sensor systems of the present invention can be attached by any suitable means, e.g. via a surface of a particle, e.g. a metal or via the polymer at the outside of a particle or can be incorporated into the particle. Different methods are known to bind molecules such as proteins, DNA, carbohydrates and other organic and inorganic compounds to metals or polymers.

Magnetic particles are widely used in biological analysis, e.g. in high-throughput clinical immunoassay instruments, sample purification, cell extraction, etc. Several diagnostic companies (Roche, Bayer, Johnson & Johnson, Abbott, BioMerieux, etc.) fabricate and sell reagents with magnetic particles, e.g. for immunoassays, nucleic-acid extraction, and sample purification. Magnetic particles are commercially available in various sizes, ranging from nanometers to micrometers. For attachment or binding of the particles to bioactive molecules, the particles may carry functional groups such as hydroxyl, carboxyl, aldehyde or amino groups. These may in general be provided, for example, by treating uncoated monodisperse, superparamagnetic particles, to provide a surface coating of a polymer carrying one of such functional groups, e. g. polyurethane together with a polyglycol to provide hydroxyl groups, or a cellulose derivative to provide hydroxyl groups, a polymer or copolymer of acrylic acid or methacrylic acid to provide carboxyl groups or an aminoalkylated polymer to provide amino groups. U.S. Pat. No. 4,654,267 describes the introduction of many such surface coatings. Other coated particles may be prepared by modification of the particles according to the U.S. Pat. Nos. 4,336,173, 4,459,378 and 4,654,267. For example, macroreticular porous polymer particles, prepared from styrene-divinylbenzene and with a diameter of 3.15 um were treated with HN0₃ to introduce —NO₂ groups at the surface of the pores. Then the particles were dispersed in an aqueous solution of Fe. The Fe²⁺ is oxidized by the NO₂ groups that leads to precipitation of insoluble iron oxy-hydroxy compounds inside the pores. After heating the iron exists as finely divided grains of magnetic iron oxides throughout the volume of the porous particles The NO₂ groups are reduced by the reaction with Fe to NH₂ groups. To fill up the pores and to introduce the desired functional groups at the surfaces, different monomers are caused to polymerize in the pores and at the surface. In the case of a preferred type of particle, the surface carries —OH groups connected to the polymeric backbone through (CH₂CH₂0) 8-10 linkages. Other preferred carry —COOH groups obtained through polymerization of methacrylic acid. For example, the NH₂ groups initially present in the particles may be reacted with a di-epoxide as described in U.S. Pat. No. 4,654,267 followed by reaction with methacrylic acid to provide a terminal vinyl grouping. Solution copolymerization with methacrylic acid yields a polymeric coating carrying terminal carboxyl groups. Similarly, amino groups can be introduced by reacting a diamine with the above product of the reaction with a diepoxide, while reaction with a hydroxylamine such as aminoglycerol introduces hydroxy groups.

The coupling of a bioactive molecule to a particle can be irreversible but can also be reversible by the use of a linker molecule for the crosslinking between particle and bioactive molecule. Examples of such linkers include peptides with a certain proteolytic recognition site, oligonucleotide sequences with a recognition site for a certain restriction enzyme, or chemical reversible crosslinking groups as those comprising a reducible disulfide group. A variety of reversible crosslinking groups can be obtained from Pierce Biotechnology Inc. (Rockford, Ill., USA).

The present invention relates to the use and positioning of magnetic field generators such as permanent magnets, current carrying wires, or electromagnets in combination with magnetoresistive sensors such as GMR sensors. Herein actuation magnetic field generators such as magnets are used to manipulate particles towards and from a sensor. Magnetic actuation relies on the tendency of magnetic particles to move toward regions of increasing magnetic field. Thus it is the gradient of the magnetic field that generates a magnetic actuation force on the particles. The actuation magnetic field generally has a gradient with a component perpendicular to the sensor surface, but it can also have a gradient with a component along the sensor surface. A magnetic field from such a magnetic field generator can be either oriented mainly perpendicular to the sensor surface or under a first angle (alpha) and/or under a second angle (beta) (see FIGS. 1 and 2). A reset magnetic field generator such as a magnet or a coil or a wire is used to restore the sensitivity of a sensor that has been distorted, by generating a well-defined magnetization profile in the sensor material. The field of a reset magnetic field generator has a component along the longitudinal axis of the magnetic sensor element. The shape of the sensor strip and the materials of which the sensor is made determine what is the optimum orientation and magnitude for achieving a well-defined sensitivity of the sensor. Depending on the field applied or the time point at which a reset magnetic field generator such as magnet is activated, the same generator can also be used as an actuation magnet. In the same context a magnetic field generator such as magnet that is repositioned during an assay can function as actuation and/or reset magnetic field generator.

The magnetic field generators for applying actuation or reset fields can be electromagnets (as illustrated in FIGS. 5 to 8), coils, or integrated wires (see FIG. 9). In a particular embodiment the magnetic field generator can be a current carrying wire, typically integrated on the same substrate. Such an integrated current wire can typically be positioned very accurately with respect to the magnetic sensor element. Furthermore, when the current-wire is located in very close proximity to the magnetic sensor element, the power dissipated in the wire can be relatively modest. The systems and method of the present invention can be equally performed with permanent magnets, wherein switching on and off of the magnetic field could be achieved by physically moving the magnets towards and away from the sensor. Some applications are best served by three magnetic field generators, e.g. for actuation towards and from the sensor surface and a reset magnetic field generator placed at another position. The number of magnetic field generators can be reduced by moving a magnetic field generator from one position to another. Thus depending on its orientation and/or placement, one single magnetic field generator can be used to attract magnetic particles to the sensor surface (actuation magnetic field generator or magnet), to pull particles away from the sensor surface or across the sensor surface (actuation magnetic field generator or magnet) or to restore the field (reset magnetic field generator or magnet). To limit the number of moving objects in the sensor system different magnetic field generators at various fixed positions is preferred. Depending on the physical restraints of the sensor system it can be more convenient to have a combination of magnetic field generators which are placed perpendicular to the sensor surface with a reset magnetic field generator, instead of a sensor system wherein actuation magnetic field generators are to be placed to have a magnetic field in an inclined position.

Also integrated on-chip current wires can be used, as in FIG. 9. One advantage is that the geometrical aspects of integrated wires are known very precisely, because such on-chip structures are generally defined by lithographic fabrication processes. This gives a well-defined magnetic field, in terms of magnitude and orientation, at the location of the sensor for a given applied current. A further advantage of integrated wires is that these can be located close to the sensor, which implies an efficient use of electrical power. A further advantage is that fewer components are needed, e.g. a separate reset coil can be omitted.

The field required by a strong magnetic field gradient to exert a reasonable actuation force on magnetic particles depends on the size and concentration of particles. Typically actuation of particles has been performed with a force perpendicular to the surface of a sensor (to either pull the particles towards the sensor surface or to pull them away from the sensor surface), but it is also possible to apply a lateral magnetic force.

The present invention provides different ways of positioning magnetic field generators around a sensor to circumvent the prior art problem of a distorted magnetization profile and sensitivity of a sensor after magnetic actuation of particles with respect to the sensor surface.

The magnetic field generator(s) that should bring the sensor in a well-defined state should generate an in-plane field component that is strong enough to substantially magnetically saturate the one or more free magnetic layers of the sensor. The magnetic saturation and subsequent relaxation of the sensor magnetization will bring the sensor in a well-defined sensitivity state. At the same time the magnetic field should be small enough to not affect the other layers in the sensor, e.g. the layers that are supposed to provide a fixed magnetization in a magneto-resistive sensor (Coehoorn, cited above).

In a first aspect the invention describes a configuration of a sensor system wherein magnetic actuation fields have an orientation other than perpendicular to the sensor surface as applied in the prior art. The actuation magnetic field generator or magnet is placed in such an orientation to generate an actuation magnetic field at a first angle (alpha) of less than 90° to the sensor surface (see FIG. 1). For reference: an angle of zero degrees is completely along the surface of the sensor, while an angle of 90 degrees is perpendicular to the sensor surface. Such an applied actuation magnetic field thus has a component along a longitudinal axis of the sensor. Even at very high field strengths, the rotation of magnetic domains on a sensor caused by the actuation magnetic field generator or magnet position at an angle that is always less than 90 degrees, will cause the magnetic domains to return to a defined position when the actuation field is removed (see FIG. 7). Actuation fields with a first angle (alpha) of 90 degrees will revert the magnetic domains at the sensor surface and are to be avoided. Using such a configuration having a sufficiently large in-plane component of the actuation field in the plane of the magnetoresistive element magnetic particles can still be actuated while the sensor is not negatively affected by the application of the magnetic actuation field. Theoretically, the magnetic actuation to be applied in accordance with this aspect of the present invention can have a direction at any first angle (alpha) other than 90 degrees (the orientation perpendicular to the surface of the sensor). Depending on the type of assay the direction of magnetic particles towards and from the sensor surface can differ. Typical positions include angles of about 75 degrees (70 to 80), 60 degrees (50 to 70 degrees) and 45 degrees (40 to 50 degrees). The actuation itself will be more efficient when the direction of the magnetic field is at a higher first angle (alpha) with the sensor surface. However, the shape of the sensor strip and the materials of which the sensor is made, determine what is the best field orientation for achieving a well-defined sensitivity of the sensor.

An example of a configuration in accordance with the present invention is shown in FIG. 7. The situation as depicted in FIG. 7 whereby the magnetic fields at the sensor surface are tilted out of the plane of the sensor surface represents an extreme situation when very strong fields are applied. The actuation magnetic field generator or magnet and the resulting magnetic field is placed at a first angle (alpha) of about 45° with respect to the surface of the sensor. This actuation field has a component along the alignment of the magnetic domains (FIG. 7b). The domains will return to their original positions after the field has been switched off (FIG. 7c). According to this embodiment wherein the actuation field is at a first angle (alpha), the movement of magnetic particles has a component along the longitudinal direction of the sensor surface. Such a configuration can be used when inlet or outlet devices are positioned above or below the sensor surface.

According to certain configurations or applications of the sensor system (e.g. the position of inlet and outlet devices) a magnetic field can be applied that has a second angle (beta) (see FIG. 2). Also in this case, the applied actuation field has a component along the direction of the magnetic domains in the free layer of the sensor (the longitudinal axis of the sensor), and after removal of the actuation field, the field of the sensor will be restored into in its original position. According to this embodiment wherein the actuation field is at a second angle (beta), the movement of the particles has a component along the lateral direction of the sensor surface. Such a configuration can be used when inlet or outlet devices are positioned along the longitudinal side of the sensor surface.

Actuation fields are in general used to pull non-selectively bound magnetic particles away from the sensor surface and/or to pull magnetic particles towards the sensor surface to speed-up the binding process and/or to pull particles across the sensor surface for binding as well as removal. Thus according to particular embodiments, actuation magnetic field generators such as magnets can be positioned under the sensor, above the sensor and both below and above the sensor.

A second aspect of the invention relates to a sensor system with actuation fields orthogonal to the sensor surface as known from the prior art, but wherein an additional magnetic field (reset field) is applied to restore the disoriented magnetization of the sensor.

In such a sensor system an actuation magnetic field generator generates a field gradient perpendicular to the surface of the sensor and an additional reset magnetic field generator or magnet is supplied that can be used to restore the magnetic orientation of the sensor (see FIG. 8). (The situation as depicted in FIG. 8 whereby the magnetic fields at the sensor surface are tilted out of the plane of the sensor surface represent an extreme situation when very strong fields are applied). This reset magnetic field generator or magnet creates for example a magnetic field component along the preferential magnetic orientation, i.e. along a largest dimension of the sensor. After actuation, a reset magnetic field generator is activated to restore the magneto-resistance sensor. Reset periods in the second range are less are suitable to reset the magnetic field.

In order to be effective a reset field should preferably have a component along the longitudinal direction of the magnetic element of the sensor. Typically, this is provided by a magnetic field oriented in the plane of the sensor surface. Depending on the configuration of the sensor device it can be desirable to have the reset magnetic field generator inclined with respect to the plane of the sensor surface under a third angle (gamma) (negative when the field of the reset magnet is pointing downwards, positive when the field of the reset magnet is pointing upwards) (see FIG. 3). Alternatively or in addition, the field of the reset magnetic field generator or magnet can be shifted with a fourth angle (delta) (positive or negative) with respect to the surface of the sensor (see FIG. 4). Alternatively or in addition the reset magnetic field generator or magnet can be also placed below or above the plane of the sensor surface. Each of these positions or a combination thereof results in the generation of a field with a component along the original direction of the magnetization of the sensor and can be used to restore a sensitivity that has been distorted by any applied actuation field.

It becomes evident that when the field generated by the reset magnetic field generator is not completely in the plane of the sensor surface but also has a component towards or away from the surface of the sensor, the reset magnetic field generator or magnet can be used as well to actuate magnetic particles to the sensor surface. Accordingly, another aspect of the present invention is a sensor device with two magnetic field generators such as magnets, as depicted in FIG. 5, wherein one magnetic field generator or magnet is positioned at one side of the sensor and has a field perpendicular to the surface of the sensor. This magnetic field generator or magnet is only used to actuate particles to or from the sensor surface. The other magnetic field generator or magnet is positioned at the other side of the sensor surface to generate a field with a first angle (alpha) and/or a second angle (beta) with respect to the sensor surface. This second magnetic field generator or magnet actuates particles towards or from the sensor surface and at the same time restores the field at the sensor surface that was distorted by any applied magnetic field. The application of a magnetic field with an in plane component can also be used to reset the free layer of the sensor, forcing it into a well-defined state before the start of a new measurement.

Another aspect of the invention relates to methods for actuating magnetic particles in a sensor system towards and from the surface of a sensor having a magnetoresistive element. Depending on the type of assay magnetic particles can be manipulated one or more times to or from the sensor surface with a magnetic field with a direction other than perpendicular to the sensor surface, i.e. a magnetic field with a component in the plane of the sensor. Such magnetic fields do not distort the magnetic domains which are present at the surface of sensor. The magnetic domains in the magnetic layer which have been distorted during the actuation get restored during a latter actuation step by a magnetic field having a component along the longitudinal axis of the surface of the sensor. Alternatively, when the last actuation step has been performed with a magnetic field with a direction perpendicular to the sensor surface, a final reset step is required without actuation using a magnetic field having a component along the longitudinal axis of the surface of the sensor. Such method can be used for example in assays wherein the magnetic particles to be measured are bound via an analyte to the measurement surface, and wherein the last actuation step has been used to remove unbound or non-specific bound particles from the measurement surface.

Any of the methods of the present invention may include a step of measuring the presence of at least one magnetic particle accumulated at the surface of the sensor.

The system of the present invention can be used for several applications wherein sensitive magnet detection is performed combined with magnetic actuation for enhancing the movement of magnetic particles towards and from a sensor surface. While detection with other methods is possible (e.g. fluorescence), the detection of magnetic particles can be performed entirely using a magnetoresistive sensor.

Other arrangements for embodying the invention will be obvious for those skilled in the art.

It is to be understood that although preferred embodiments, specific constructions and configurations, as well as materials, have been discussed herein for devices and methods according to the present invention, various changes or modifications in form and detail may be made without departing from the scope and spirit of this invention. The invention is illustrated by the Examples provided below which are to be considered for illustrative purposes only and the invention is not limited to the specific embodiments described therein.

### EXAMPLES

### Example 1

### Magnetic Actuation of Magnetic Particles Followed By GMR Measurement

In a first setting a small amount of magnetic particles, e.g. 10 particles, which is close to the detection limit of a GMR sensor, is allowed to settle by gravity for a period long enough to bring all particles to the surface of the GMR sensor. The concentration of particles on the GMR sensor is determined

In a second setting the same amount of particles is moved from and towards the GMR sensor using magnetic actuation coils placed perpendicular to the GMR sensor surface. Subsequently no particles could be detected via GMR measurement, due to the altered sensitivity.

In a third setting the same amount of particles was moved from and towards the GMR sensor using magnetic actuation coils placed at an angle of 75° with the GMR sensor surface. Particles can be detected and the concentration of particles is now about the same value as in the control experiment.

### Example 2

### Magnetic Actuation And Resetting On Magnetoresistive Sensors

The present example illustrates the effect of applied magnetic actuation fields and magnetic reset field on a magnetoresistive sensor.

An actuation field is applied by a coil which generates a field perpendicular to the sensor surface. The reset coil is aligned along the long axis of the magneto-resistive sensor. Magnetic particles were not present during the measurement. The used currents are varied and listed below. When used, the reset pulse is applied just before a measurement point. When the reset pulse is applied the sensor is always in the same state and not dependent on the actuation current. FIG. 10 depicts the measured signal of a magneto-resistive sensor as a function of time. The events performed at different time points (indicated with arrows in the Figure) are as follows:

1: start of the measurements without actuation and without reset pulse.
2: start of the actuation with 250 mA without reset pulse.
3: continuation of the actuation with 500 mA without reset pulse.
4: continuation of the actuation with 1 A without reset pulse.
5: continuation of the actuation with 2 A without reset pulse.
6: start of reset pulse without actuation.
7: start of actuation with 250 mA followed by reset pulse.
8: continuation of the actuation with 500 mA followed by reset pulse.
9: continuation of the actuation with 1 A followed by reset pulse.
10: continuation of the actuation with 2 A followed by reset pulse.
11: perturbation of the sensor by the presence of a permanent magnet during the measurement (followed by reset pulse).
12: removal of the permanent magnet with reset pulse.

The above experiment shows that a non-perpendicular reset pulse gives a reproducible sensor readout after a perturbing magnetic-particle actuation field has been applied.

### Example 3

### Immunoassay With Magnetic Actuation And GMR Detection

The present example shows a competition assay. A known amount of morphine is coated on the bottom of a multiwell plate. A buffer containing superparamagnetic beads (200 nm) functionalized with antibodies against morphine is added to the wells. The plate is put on a GMR sensor and magnetic particles are actuated for one and five minutes with a NbFeB magnet. After the actuation the field at the GMR sensor is reset with a magnetic field with an in-plane component in accordance with the present invention. This device is capable of detecting morphine with a sensitivity of about 5 to 10 ng. Also, using the present device, all morphine present on the plate could be detected (see the first data point of the control experiment in FIGS. 11 and 12 wherein no morphine is added to the buffer).

The specificity of the assay is shown by adding free morphine to the buffer which will compete with the antibodies on the magnetic particles. As shown in FIGS. 11 and 12, increasing amounts of free morphine prevent the binding of magnetic particles to the surface of the well on the plate.

1. A system for measuring the presence of at least one magnetic particle at the surface of a sensor comprising a sensor with a magnetoresistive element and comprising one or more magnetic field generators arranged around the sensor at a distance arranged to generate a magnetic field at the sensor, characterized in that one or more magnetic field generators generate a field with a component in the plane of the sensor.

2. The system according to claim 1 wherein one or two magnetic field generators are positioned each to generate a magnetic field with a first angle (alpha) with a longitudinal axis of the sensor.

3. The system according to claim 1 wherein said one or two magnetic field generators are placed to generate each a magnetic field with a second angle (beta) to the transverse axis of the sensor.

4. The system according to claim 1 wherein one or two magnetic field generators are positioned to generate a magnetic field at an angle perpendicular to the surface of the sensor, and further comprising a magnetic field generator which is placed to generate a magnetic field with a third angle (gamma) and/or fourth angle (delta) with the surface of the sensor.

5. The system according to claim 1 wherein one magnetic field generator is positioned to generate a magnetic field perpendicular to the surface of the sensor, and further comprising a second magnetic field generator which is positioned to generate a magnetic field with a first angle (alpha) to a longitudinal axis of the sensor and/or a second angle (beta) to a transverse axis of the sensor.

6. The system according to claim 1, wherein the sensor is a GMR sensor.

7. The system according to claim 1, wherein one or more magnetic field generators are electromagnets.

8. The system according to claim 1, wherein the field generator is an on-chip current wire.

9. The system of claim 1 further comprising magnetic particles.

10. The system according to claim 9 wherein an analyte is bound to said magnetic particles.

11. Use of magnetic field generators arranged around a magnetoresistive element of a sensor to manipulate magnetic particles towards and from the surface of said sensor whereby the magnetization of the surface prior to the manipulation is maintained or restored compared to said magnetic field prior to said manipulation.

12. The use according to claim 11 wherein an analyte is bound to said magnetic particles.

13. A method for manipulating magnetic particles towards and from the surface of a sensor with a magnetoresistive element comprising the steps of:
a1) manipulating said particles one or more times to or from the sensor surface with a magnetic field with a direction other than perpendicular to the sensor surface, or
a2) manipulating said particles one or more times to or from the sensor surface with a magnetic field with a direction perpendicular to the sensor surface followed by applying a magnetic field having a component along a longitudinal axis of the surface of the sensor.

14. The method according to claim 13 further comprising the step of measuring the presence of at least one magnetic particle accumulated at the surface of the sensor.

15. The method according to claim 13 wherein the sensor is a GMR sensor.

16. The method according to claim 13 wherein the magnetic fields are generated by electromagnets or coils or wires.
